(19) United States
(12) Patent Application Publication
(10) Pub. No.: US 2022/0229138 A1
(43) Pub. Date: Jul. 21, 2022

(54) PROCESS OF ENHANCING NITROGEN VACANCY (NV) CENTER SPIN EXCITATION IN HYPERPOLARIZATION APPLICATION

(71) Applicants: MASTER DYNAMIC LIMITED, Hong Kong (CN); GOLDWAY TECHNOLOGY LIMITIED, Hong Kong (CN)

(72) Inventors: Ka Wing CHENG, Hong Kong (CN); Kong CHAN, Hong Kong (CN); Chun Hong SHAM, Hong Kong (CN); Juan CHENG, Hong Kong (CN); Koon Chung HUI, Hong Kong (CN)

(73) Assignees: MASTER DYNAMIC LIMITED, Hong Kong (CN); GOLDWAY TECHNOLOGY LIMITIED, Hong Kong (CN)

(21) Appl. No.: 17/609,355

(22) PCT Filed: Oct. 10, 2019
(86) PCT No.: PCT/CN2019/110445

§ 371 Date: Nov. 5, 2021

(30) Foreign Application Priority Data
May 7, 2019 (HK) 19123368.3

(51) Int. Cl. G01R 33/56; G01R 33/28

(52) U.S. Cl. CPC G01R 33/5601; G01R 33/282

(57) ABSTRACT

A process for enhancing polarization of ¹³C for subsequence MRI imaging, the process comprising providing a suspension consisting of a first plurality of particulates having NV centers and a second plurality of particulates for providing internal reflection of light with wavelength for the excitement of NV centers and ¹³C; and applying light, magnetic field and microwave to said suspension, such that the NV centers are polarized and such that the electron spins of the VN centres are transferred to ¹³C atoms upon the Rabi frequency of the NV centres matching the Larmor frequency of ¹³C; wherein the particulates of the second plurality reflect and transmit the light through the suspension such that said light is distributed through said suspension.

### TECHNICAL FIELD

The present invention relates to a process for enhancing nitrogen vacancy spin, and in particularly, the present invention provides a process for enhancing nitrogen vacancy spin for subsequent magnetic resonance imaging (MRI) applications.

### BACKGROUND OF THE INVENTION

Magnetic resonance imaging (MRI) has been widely used in the medical discipline for obtaining three-dimensional structural information from a human body of a subject.

By obtaining a three-dimensional image, medical practitioners are able to effectively see through the organs of a patient or subject, and determine if there are any structural abnormalities within the body as well as determine that an organ does not have structural abnormalities.

One such abnormality is the presence of tumor tissue, often associated with an organ. Traditional MRI techniques detect 1H nuclei inside the body of a patient of subject, such that the water and fat distribution can be seen. Also ionizing radiation is involved in such a process, it is generally considered to be a safer investigation method than X-ray imaging techniques.

However, detecting 1H nuclei alone cannot always distinguish normal tissue and cancerous tissue and as such, the techniques can be considered to be less applicable than X-ray computed tomography (CT) and positron emission tomography (PET).

Therefore, in order to enhance the contrast between normal and cancerous tissue of a patient or subject, contrast agents can be introduced into the body of the patient or subject. These MRI contrast agents typically contain gadolinium, which, however, has certain toxicity towards the kidneys and the nervous system.

Patients or subjects having rental diseases are considered susceptible to kidney failure after injection of gadolinium-based contrast agents into the body. Moreover, gadolinium can remain in human body for a prolonged period time after MRI scanning is completed, which also increases the risk of patient safety related issues and concerns.

Apart from gadolinium-based contrast agents, there has been some research on ¹³C nuclei based MRI imaging in order to distinguish normal and cancerous tissues. Carbon, as is known, is considered the building block of all organic compounds.

Since ¹³C nuclei are stable, there is considered no harm in using ¹³C for MRI imaging in living organisms. However, the natural abundance of ¹³C nuclei in carbon is only 1.1%, which is much smaller than the natural abundance of 99.98% of 1H nuclei in hydrogen. Moreover, ¹³C signal in MRI is much weaker than 1 H.

These two factors together can be considered to make MRI by ¹³C very difficult practically. However, there has been technologies for enriching ¹³C abundance in biomolecules. Therefore, ¹³C enhanced compounds with high purities can be obtained commercially.

Regarding the low signal of ¹³C in comparison to 1H, there are also techniques for signal enhancement in the art. At room temperature, the nuclear spin alignment of ¹³C within a magnetic field is little under thermal equilibrium.

In order to enhance the ¹³C signal, the ratio of aligned nuclear spin under magnetic field is needed to be greatly increased beyond thermal equilibrium. This phenomenon is called hyperpolarization within the art.

Dynamic nuclear polarization (DNP) is a method which can be used to hyperpolarize ¹³C so that ¹³C signal can be enhanced by 10,000-fold compared to thermal equilibrium in room temperature. This makes use of compounds with radicals to provide lone pair electrons, whose aligned spins can polarize the nuclear spins of ¹³C. By adding radicals into C compounds at around 1 K in a magnetic field of 4.6 T to 5 T for 30 min to 90 min, the ¹³C nuclear spin can be hyperpolarized.

As the radicals used in DNP have certain toxicity to human cells and the DNP process has to be done in cryo-environment, there have been proposed in the art other methods developing for the hyperpolarization of ¹³C.

This can be done by optical hyperpolarization of the electron spins of nitrogen-vacancy (NV) centres in nanodiamonds (NDs) under room temperature. A laser can be used for optical pumping, so as to provide stimulation, the electron spins of NV centres in nanodiamonds. The electron spins will then be transferred to ¹³C atoms when the Rabi frequency of the NV centres match the Larmor frequency of ¹³C.

### OBJECT OF THE INVENTION

It is an object of the present invention to provide a process for enhancing nitrogen vacancy spin for subsequent magnetic resonance imaging (MRI) applications, which overcomes or at least partly ameliorates at some deficiencies as associated with the prior art.

### SUMMARY OF THE INVENTION

In a first aspect, the present invention provides a process for enhancing polarization of ¹³C for subsequence MRI imaging, the process comprising:
providing a suspension consisting of a first plurality of particulates having NV centers and a second plurality of particulates for providing internal reflection of light with wavelength for the excitement of NV centers and ¹³C; and
applying light, magnetic field and microwave field to said suspension, such that the NV centers are polarized and such that the electron spins of the NV centres are transferred to ¹³C atoms upon the Rabi frequency of the NV centres matching the Larmor frequency of ¹³C;
wherein the particulates of the second plurality reflect and transmit the light through the suspension such that said light is distributed through said suspension.

The first plurality of particulates may be comprised of nanodiamonds. The nanodiamonds preferably are sized in the range of from 30 nm to 999 nm.

The second plurality of particulates may be comprised of minidiamonds.

The second plurality of particulates may be comprised of microdiamonds. The microdiamonds may be sized in the range of from 1 μm to 100 μm.

The second plurality of particulates may be comprised of quartz.

The second plurality of particulates may be comprised of glass.

The second plurality of particulates is comprised of two or more of minidiamonds, microdiamonds, quartz or glass.

The light may be applied by an optical laser.

The ¹³C for subsequence MRI imaging may be derived from the first plurality of particulates.

The ¹³C for subsequence MRI imaging may be provided by way of a further chemical composition which is present within said suspension. The further chemical composition which is present within said suspension may be a pyruvate.

After the enhancing polarization of ¹³C the first plurality of particulates, the second plurality of particulates are filtered out of the suspension, leaving hyperpolarized further chemical composition for injection into the human body for MRI imaging.

After the enhancing polarization of ¹³C the first plurality of particulates, the second plurality of particulates are filtered out of the suspension, leaving hyperpolarized pyruvate for injection into the human body for MRI imaging.

The microwave may be a pulsed microwave field. The light may be provided by a pulse laser.

The light may be pulsed light. The light is preferably monochromatic.

In a second aspect, the present invention provides a suspension for enhanced polarization of ¹³C and MRI imaging, said suspension comprising of a first plurality of particulates having NV centers and a second plurality of particulates for providing internal reflection of light with wavelength for the excitement of NV centers and ¹³C.

The first plurality of particulates may be comprised of nanodiamonds. The nanodiamonds are preferably sized in the range of from 30 nm to 999 nm.

The second plurality of particulates may be comprised of minidiamonds.

The second plurality of particulates is comprised of microdiamonds. The microdiamonds are preferably sized in the range of from 1 μm to 100 μm.

The second plurality of particulates may be comprised of quartz.

The second plurality of particulates may be comprised of glass.

The second plurality of particulates may be comprised of two or more of minidiamonds, microdiamonds, quartz or glass.

The ¹³C for subsequence MRI imaging may be derived from the first plurality of particulates.

The suspension may further comprise a further chemical composition as a source of ¹³C. The suspension may further comprise a pyruvate as a source of ¹³C.

In a third aspect, the present invention provides process using refractive material as optical repeaters for dispersing light into and throughout an opaque powder, for enhancing spin excitation of the powder in a hyperpolarization application.

The opaque powder is preferable nanodiamonds or microdiamonds.

The opaque powder may be nanodiamonds or microdiamonds blended with other chemicals.

The optical repeaters may be provided by microdiamonds, minidiamonds or crushed quartz, glass or the like, or combinations thereof.

### BRIEF DESCRIPTION OF THE DRAWINGS

In order that a more precise understanding of the above-recited invention can be obtained, a more particular description of the invention briefly described above will be rendered by reference to specific embodiments thereof that are illustrated in the appended drawings. The drawings presented herein may not be drawn to scale and any reference to dimensions in the drawings or the following description is specific to the embodiments disclosed.

FIG. 1 shows a schematic representation of a system for use in the present invention, for the for stimulation of the electron spins of NV centres in nanodiamonds;

FIG. 2 shows a schematic representation of an enlarged view of the specimen or sample tube of FIG. 1;

FIG. 3a shows an enlarged view of the feature around 291 mT in the process of the present invention; and

FIG. 3b shows the enhancement of polarisation (signal) in which the full spectrum of FIG. 3a is shown.

### DETAILED DESCRIPTION OF THE DRAWINGS

The present inventors have identified shortcomings of the problems with the prior art, and have provided a system and process which is more consistent and reliable, and overcomes the problems of the prior art.

### Problems of Prior Art Identified by Present Inventors

The present invention relates to hyperpolarization of ¹³C by the hyperpolarization of the electron spins of nitrogen-vacancy (NV) centres in nanodiamonds (NDs), and transfer to electron spin to ¹³C atoms.

The present inventors have identified that as nanodiamonds are optically opaque, optical pumping for providing excitation to the electron spins of NV centres in nanodiamonds is not efficient.

In view of this observation and phenomena, the present inventors have sought improve the efficiency of optical hyperpolarization of nanodiamonds for ¹³C.

The present inventors have thus provided a method to increase the efficiency of optical hyperpolarization of nanodiamonds for ¹³C.

Such a method of the present invention enhances dispersion of laser light into opaque nanodiamond powder.

### Invention Background Theory

Diamonds contain Nitrogen Vacancy (NV) centres with one negative charge captured from the surroundings. The diamond NV-centres are paramagnetic with spin S=1 with a large zero field splitting, with D=2.87 GHz wherein D is the energy difference between electron spin state of zero-field splitting of NV center, the energy range is in microwave band.

Laser can be used for optical pumping, providing excitation, to the electron spins of NV centres in nanodiamonds.

The electron spins of the NC centres can then be transferred to ¹³C atoms when the Rabi frequency of the NV centres match the Larmor frequency of ¹³C.

However, the present inventors have noted and identified that nanodiamonds typically contain a lot of different impurities other than NV centres. For example, different kinds of nitrogen centres, surface attached amorphized carbon for example exist.

Therefore, nanodiamonds are essentially opaque, and the present inventors have noted that only the NV centres on surface of a powder of nanodiamonds can be efficiently excited by the laser.

### Present Invention

In accordance with the present invention, a method has been proposed and developed to enhance the efficiency of optical pumping for stimulation of the electron spins of NV centres in nanodiamonds.

The present invention achieves such enhanced efficiency of optical pumping by introducing “optical repeaters” within a nanodiamond powder, by providing a plurality of such “optical repeaters” dispersed throughout the nanodiamond powder.

The present inventors have provided such “optical repeaters” by introducing particulates for providing internal reflection of light with wavelength for the excitement of NV centers and ¹³C.

Such particulates can be cut and polished minidiamonds for example, which have sizes around 1 mm, which are introduced into the powder of nanodiamonds. It has been found that the high refractive index (n=2.4) of diamonds causes a lot of total internal reflection inside the minidiamonds.

Alternatively, quartz or glass for example can be used as such optical repeaters to internally reflect light in the invention.

Further, a mixture of two or more different materials can be used as the optical repeaters, such as two or more of a plurality of minidiamonds, quartz or glass could be used to provide optical repeaters in accordance with the present invention.

Therefore, in accordance with the present invention, each “optical repeater” suspended within the nanodiamond powder can disperse laser light into different directions and reach another “optical repeater”, thus allowing the added minidiamonds, for example, to act as optical repeaters to advantageously transmit laser light deep into the nanodiamond powder.

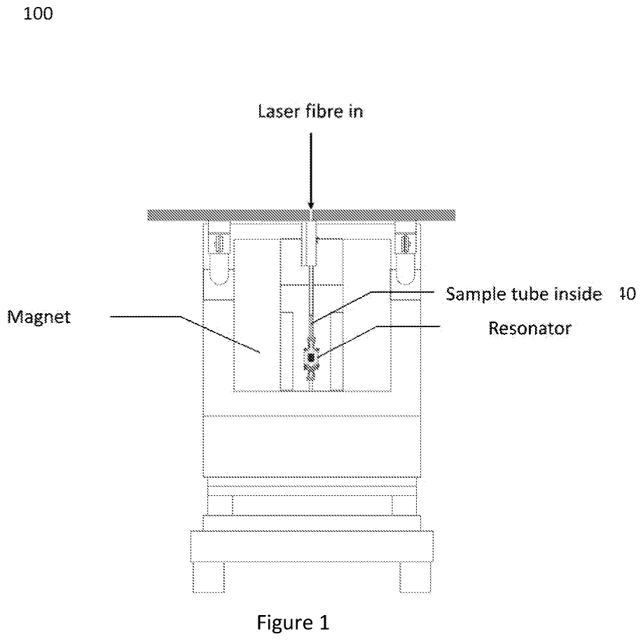

Referring to FIG. 1, there is shown a system 100 for use in the present invention, for the stimulation of the electron spins of NV centres in nanodiamonds. As is shown, the system 100 includes a magnet 110 for providing a magnetic field, a resonator 120 for applying a microwave field, a laser light source 130 for providing optical pumping which may introduce light via an optical fibre, and a specimen tube 140 for containing a suspension of nanodiamonds and “optical repeaters”.

Any kinds of resonator may be used, such as pulsed or continuous microwave resonators.

Light can be provided by a laser for example. The light may be pulsed light. Preferably monochromatic light is used. Although the light source is preferably a laser light source, other light sources may be utilised in alternate configurations and embodiments.

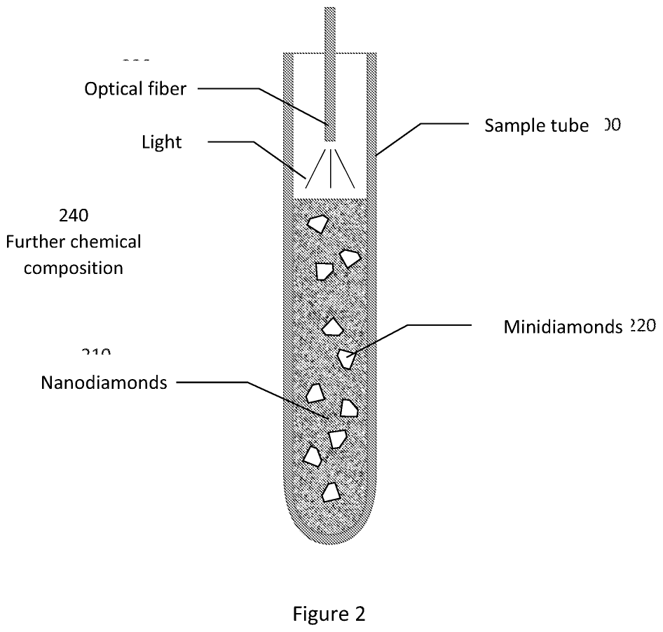

Referring now to FIG. 2, there is shown an enlarged view of the specimen or sample tube 200 which is depicted as item 140 of FIG. 1.

Within the sample tube 200 is an embodiment of a suspension consisting of a first plurality of particulates 210 having NV centers, whereby the first plurality of particulates is typically a plurality of nanodiamonds.

The suspension further comprises and a second plurality of particulates 220 for providing internal reflection of light with wavelength for the excitement of NV centers and ¹³C, which are to function as “optical repeaters” as described in accordance with the invention.

As shown, in the present embodiment, the second plurality of particulates 220 are “minidiamonds”. However alternatively in other embodiments, quartz or glass for example can be used to internally reflect light and be used as “optical repeaters”. In alternate embodiments, the “optical repeaters” may be a mixture of two or more different types of particulates.

Light is applied by optical fibre 230, and a magnetic field and microwave field are also applied to the suspension in the sample tube 200, such that the NV centers of the first plurality of particulates, which are nanodiamonds in the present embodiment, are polarized and the electron spins of the NV centres of the nanodiamonds will then be transferred to ¹³C atoms when the Rabi frequency of the NV centres match the Larmor frequency of ¹³C.

In accordance with invention and as described above, the particulates of the second plurality reflect and transmit the light through the suspension such that said light is distributed through the suspension, thus acting as optical repeaters.

Hence, in accordance with the present invention more nanodiamonds can absorb laser light, and thus the present invention provides for more efficient optical pumping.

The ¹³C for subsequence MRI imaging, as is described further below, may be derived from the first plurality of particulates. Alternatively, the suspension in tube 200 may further comprising a further chemical composition as a source of ¹³C. The further chemical, for example, may be a pyruvate as a source of ¹³C.

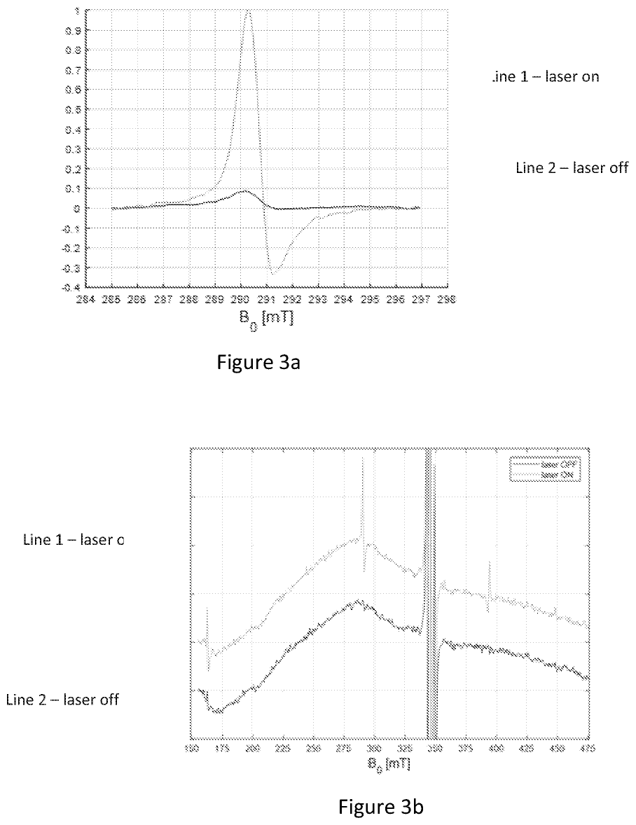

Referring to FIGS. 3a and 3b, as is shown, enhancement of NV centre by optical pumping utilizing light at a wavelength of 532 nm, using a 220 mW fibre optic positioned 4 mm above sample and the microwave signal being a pulsed microwave field, in an arrangement of FIG. 2, is now shown.

The suspension used was 5 milligram (mg) ND sample with diamond ‘rocks’ to help scatter laser light into the opaque ND powder.

Now referring to FIG. 3a, there is shown an enlarged view of the feature around 291 mT, with line 1 indicating “laser on”, and line 2 indicating “laser off”, with signal intensity shown on the vertical axis in arbitrary units (au).

As is shown in FIG. 3b, the enhancement of polarisation (signal) is x 14.7 in which the full spectrum is shown.

Thus, optical pumping with 532 nm laser and fibre optic with 220 mW output at the tip was shown to be effective. The polarisation of the triplet state (S=1) of diamond NV center was enhanced up to a factor of 15 with optical pumping in this arrangement in accordance with the present invention.

In accordance with the invention, as discussed above, other materials with high refractive indices and transparent to light will also work as “optical repeaters” such as quartz or glass.

One important requirement of the optical repeaters is those materials cannot have electron paramagnetic resonance (EPR) signal in the detection range of nanodiamonds. Otherwise, the EPR signal of the nanodiamonds will be overlapped and interfered with. Quartz crushed from an EPR tube for example, which doesn't have any signal to EPR, can also serve in this process of the present invention.

The size of nanodiamonds, when used as the first plurality of particulates, is preferably in the range of 30 nm-999 nm. Microdiamonds, when used as the second plurality of particulates with sizes of 1 μm-100 μm can also be used as the “optical repeaters”.

In an embodiment of the present invention, within the specimen tube preferably, ¹³C enriched pyruvate, nanodiamonds and minidiamonds are put and mixed together, for subsequent hyperpolarisation during the hyperpolarization process.

Then, after the hyperpolarization process, the nanodiamonds and minidiamonds are filtered out of the mixture, leaving behind hyperpolarized pyruvate which can be subsequently injected to the human body for the purpose of MRI imaging.

Within the present specification, the term “suspension” is used and understood to mean that the second plurality of particulates is mixed within and suspended or distributed within the first plurality of particulates. As such, the first plurality may be considered dispersion medium through which the particles of the second plurality of particulates is dispersed throughout and are essentially considered suspended within the first plurality of particulates.

1.-19. (canceled)

20. A suspension for enhanced polarization of ¹³C and MRI imaging, said suspension comprising of a first plurality of particulates having NV centers and a second plurality of particulates for providing internal reflection of light with wavelength for the excitement of NV centers and ¹³C.

21. The suspension according to claim 20, wherein first plurality of particulates is comprised of nanodiamonds, and wherein the nanodiamonds are sized in the range from 30 nm to 999 nm.

22. (canceled)

23. The suspension according to claim 2, wherein the second plurality of particulates is comprised of minidiamonds or the second plurality of particulates is comprised of microdiamonds or the second plurality of particulates is comprised of quartz or the second plurality of particulates is comprised of glass.

24.-27. (canceled)

28. The suspension according to claim 20, wherein the second plurality of particulates is comprised of two or more of minidiamonds, microdiamonds, quartz or glass.

29.-31. (canceled)

32. A process using refractive material as optical repeaters for dispersing light into and throughout an opaque powder, for enhancing spin excitation of the powder in a hyperpolarization application.

33. The process according to claim 32, wherein the opaque powder is nanodiamonds or microdiamonds, and wherein the nanodiamonds or microdiamonds is blended with other chemicals.

34. (canceled)

35. The process according to claim 32, wherein the optical repeaters are provided by microdiamonds, minidiamonds or crushed quartz, glass or the like, or combinations thereof.

36. A process for enhancing polarization of ¹³C for subsequence MRI imaging, the process comprising:
providing a suspension according to claim 20; and
applying light, magnetic field and microwave field to said suspension, such that the NV centers are polarized and such that the electron spins of the NV centres are transferred to ¹³C atoms upon the Rabi frequency of the NV centres matching the Larmor frequency of ¹³C;
wherein the particulates of the second plurality reflect and transmit the light through the suspension such that said light is distributed through said suspension.

37. The process according to claim 36, wherein said light is applied by an optical laser.

38. The process according to claim 36, wherein ¹³C for subsequence MRI imaging is derived from the first plurality of particulates.

39. The process according to claim 36, wherein ¹³C for subsequence MRI imaging is provided by way of a further chemical composition which is present within said suspension. and wherein the further chemical composition which is present within said suspension is a pyruvate.

40. The process according to claim 39, wherein after the enhancing polarization of ¹³C the first plurality of particulates and the second plurality of particulates are filtered out of the suspension, leaving the hyperpolarized further chemical composition for injection into the human body for MRI imaging.

41. The process according to claim 40, wherein after the enhancing polarization of ¹³C the first plurality of particulates and the second plurality of particulates are filtered out of the suspension, leaving hyperpolarized pyruvate for injection into the human body for MRI imaging.

42. The process according to claim 36, wherein the microwave is a pulsed microwave field.

43. The process according to claim 36, wherein the light is provided by a pulse laser.

44. The process according to claim 36, wherein the light is pulsed light.

45. The process according to claim 36, wherein the light is monochromatic.
